(19) United States
(12) Patent Application Publication
(10) Pub. No.: US 2017/0092712 A1
(43) Pub. Date: Mar. 30, 2017

(54) VIA CAPACITOR

(71) Applicants: Joseph R. Siegel, Boxborough, MA (US); Lawrence A. Bair, Boxborough, MA (US); Bryan Black, Austin, TX (US); Michael Su, Austin, TX (US)

(72) Inventors: Joseph R. Siegel, Boxborough, MA (US); Lawrence A. Bair, Boxborough, MA (US); Bryan Black, Austin, TX (US); Michael Su, Austin, TX (US)

(21) Appl. No.: 14/865,664

(22) Filed: Sep. 25, 2015

(51) Int. Cl. H01L 49/02

(52) U.S. Cl. CPC H01L 28/60

(57) ABSTRACT

Various through silicon via capacitors and methods of fabricating the same are disclosed. In one aspect, an apparatus is provided that includes a semiconductor substrate with a portion doped with a first impurity type and a doped region of a second impurity type in the portion of the semiconductor substrate. The doped region is operable to function as a first capacitor plate. A first via hole is in the doped region. The first via hole has a first sidewall. A first insulating layer is on the first sidewall. The first insulating layer is operable to function as a capacitor dielectric. A first conductive via is in the first via hole. The first conductive via is operable to function as a second capacitor plate.

### BACKGROUND OF THE INVENTION

1. Field of the Invention

This invention relates generally to semiconductor processing, and more particularly to semiconductor chip devices with interposers and methods of making and using the same.

2. Description of the Related Art

All integrated circuits require electrical power to operate, and packaged integrated circuits, which consist of a semiconductor chip mounted on a package substrate, are no exception. Power is normally delivered to integrated circuits via a power supply and some form of power delivery network. Although currently-available power supplies are designed to supply stable voltages, the actual power delivered to integrated circuits can contain significant amounts of noise. There are many sources of noise, such as voltage fluctuations caused by transient currents due to on-die switching devices, other devices coupled to the power supply, electromagnetic interference and other causes.

To address issues associated with power supply noise, conventional semiconductor chip packages use decoupling capacitors. Many of these decoupling capacitors are mounted to the carrier substrate. In one conventional variant, the decoupling capacitors are mounted to the die side of the carrier substrate around the periphery of the die. In another conventional variant, the decoupling capacitors are mounted to the underside of the carrier substrate. In the first conventional variant, the electrical pathways from a given underside input/output pad to a die side decoupling capacitor can be large enough to diminish the effectiveness of the decoupling capacitor as a filter. The same may be true for the second conventional variant since the undermounted capacitors are not tied directly to the printed circuit board, but instead rely on the pads and other metallization structures within the carrier substrate to establish connections with the printed circuit board.

To provide greater signals and data bandwidths, designers have begun to turn to 3D stacking of semiconductor chips on interposers. Typical conventional interposers are fabricated from a semiconductor substrate and patterned with metallization using the same types of techniques traditionally used for semiconductor dies, albeit at sometimes larger geometries. An interposer populated with multiple chips is subsequently mounted on a package substrate. Providing effective decoupling capacitance for interposer-based packages remains a technical challenge. One conventional solution involves fabricating one or more metal-insulator-metal (MIM) capacitors in the metallization layers of the interposer. This may affect packing density of other interconnect structures.

The present invention is directed to overcoming or reducing the effects of one or more of the foregoing disadvantages.

### SUMMARY OF THE INVENTION

In accordance with one aspect of the present invention, a method of manufacturing a capacitor is provided that includes forming a doped region of a first impurity type in a portion of a semiconductor substrate. The portion of the semiconductor substrate is doped with a second and opposite impurity type. The first doped region is operable to function as a first capacitor plate. A first via hole is formed in the doped region. The first via hole has a first sidewall. A first insulating layer is formed on the first sidewall. The first insulating layer is operable to function as a capacitor dielectric. A first conductive via is formed in the first via hole. The first conductive via is operable to function as a second capacitor plate.

In accordance with another aspect of the present invention, a method of manufacturing is provided that includes fabricating a plurality of through silicon vias in a semiconductor substrate and fabricating a plurality of through silicon via capacitors in the semiconductor substrate. The through silicon via capacitors are fabricated by forming plural doped regions of a first impurity type plural portions of a semiconductor substrate. The portions of the semiconductor substrate are doped with a second and opposite impurity type. The doped regions are operable to function as first capacitor plates. Plural first via holes are formed in the doped regions. The first via holes have first sidewalls. Plural first insulating layers are formed on the first sidewalls. The first insulating layers are operable to function as capacitor dielectrics. Plural first conductive vias are formed in the first via holes. The first conductive vias are operable to function as second capacitor plates.

In accordance with another aspect of the present invention, an apparatus is provided that includes a semiconductor substrate with a portion doped with a first impurity type and a doped region of a second impurity type in the portion of the semiconductor substrate. The doped region is operable to function as a first capacitor plate. A first via hole is in the doped region. The first via hole has a first sidewall. A first insulating layer is on the first sidewall. The first insulating layer is operable to function as a capacitor dielectric. A first conductive via is in the first via hole. The first conductive via is operable to function as a second capacitor plate.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of an interposer that includes one or more TSV capacitors;

FIG. 2 is a pictorial view depicting a portion of FIG. 1 depicted at greater magnification;

FIG. 3 is an exploded pictorial view of an exemplary embodiment of a TSV capacitor;

FIG. 4 is a pictorial view of an exemplary embodiment of a TSV capacitor;

FIG. 5 is a sectional view of FIG. 1 taken at section 5-5 and depicted at greater magnification;

FIG. 6 is a sectional view like FIG. 5 but depicting an exemplary hole formation process;

FIG. 7 is a sectional view like FIG. 6 but depicting an exemplary impurity ion introduction step;

FIG. 8 is a sectional view like FIG. 7 but depicting mask removal;

FIG. 9 is a sectional view like FIG. 8 but depicting exemplary masking and patterning;

FIG. 10 is a sectional view like FIG. 9 but depicting exemplary trench or hole formation in advance of via formation;

FIG. 11 is a sectional view like FIG. 10 but depicting exemplary liner insulation layer fabrication;

FIG. 12 is a sectional view like FIG. 11 but depicting exemplary conductive via fabrication;

FIG. 13 is a sectional view like FIG. 12 but depicting exemplary passivation laminates and patterning;

FIG. 14 is a sectional view like FIG. 13 but depicting exemplary metallization and interlevel dielectric film fabrication;

FIG. 15 is a sectional view like FIG. 14 but depicting application of an exemplary carrier wafer;

FIG. 16 is a sectional view like FIG. 15 but depicting exemplary interposer thinning;

FIG. 17 is a sectional view like FIG. 16 but depicting exemplary passivation laminate on the interposer front side;

FIG. 18 is a sectional view like FIG. 17 but depicting exemplary interconnect structure fabrication on the interposer front side;

FIG. 19 is a sectional view like FIG. 18 but depicting exemplary mounting of a semiconductor chip on the exemplary interposer and electrical inputs thereto; and

FIG. 20 is a sectional view like FIG. 19 but depicting an exemplary semiconductor chip fabricated with an exemplary TSV capacitor.

### DETAILED DESCRIPTION OF SPECIFIC EMBODIMENTS

Through silicon via (TSV) capacitors may be constructed in a semiconductor substrate, such as an interposer or a semiconductor chip. A TSV capacitor may include a conductive via positioned in a via hole to serve as a first capacitor plate. A via hole liner insulating layer serves as a capacitor dielectric and a doped semiconductor region surrounding the via hole liner insulating layer functions as a second capacitor plate. Various metallization structures can be connected to the first and second plates to provide capacitance for various purposes. Additional details will now be described.

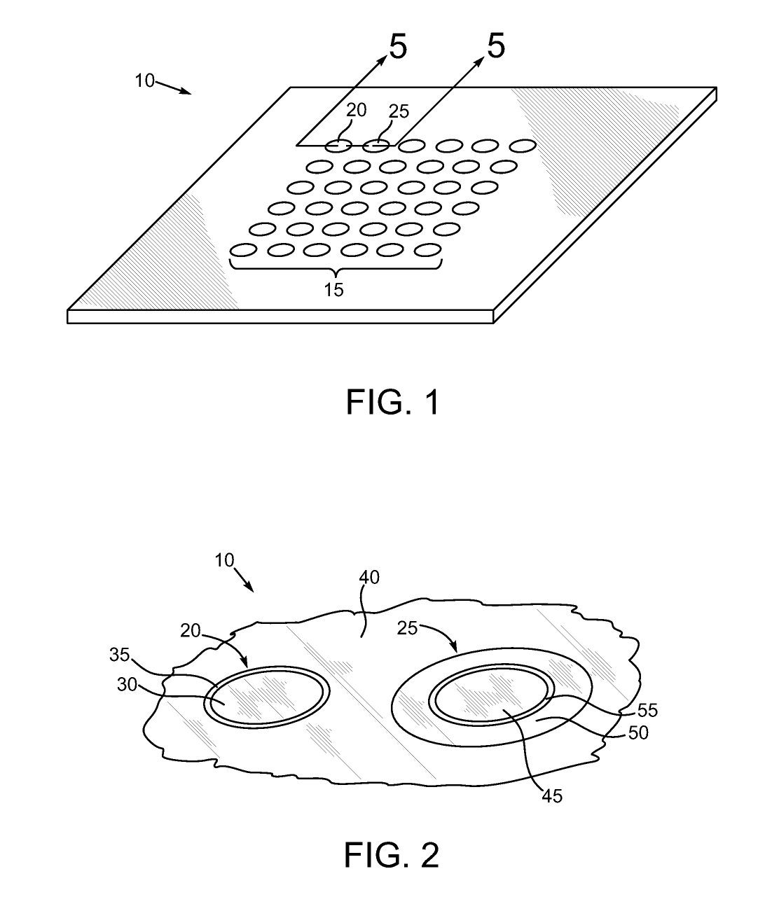

In the drawings described below, reference numerals are generally repeated where identical elements appear in more than one figure. Turning now to the drawings, and in particular to FIG. 1, therein is depicted a pictorial view of an exemplary embodiment of a semiconductor substrate 10, which may be populated with plural TSVs 15. The semiconductor substrate 10 may be an interposer or semiconductor chip and may be singulated or part of a wafer. The term “TSV” is used herein merely for convenience as the semiconductor substrate 10 may be composed of silicon, germanium, semiconductor-on-insulator materials, or other suitable interposer materials. Therefore, the term “silicon” in conjunction with term TSV herein is not intended to be limiting of a particular material. Only the tops of the TSVs 15 are visible in FIG. 1. Additional aspects of the structure of the TSVs 15 will be shown in subsequent figures and discussed below. As described in more detail below, the TSVs 15 may serve as both ohmic electrical pathways through the semiconductor substrate 10 and also as capacitors for decoupling capacitance or other needs. Two of the TSVs 15 are separately labeled 20 and 25, respectively, and will be used to describe additional features of the semiconductor substrate 10 in subsequent figures.

Attention is now turned to FIG. 2, which is a small portion of the semiconductor substrate 10 depicted in FIG. 1 that includes the TSVs 20 and 25. The TSV 20 is fabricated in the traditional way to include a conducting via 30 surrounded by an insulating liner 35. The insulating liner 35 separates the via 30 electrically from the surrounding semiconductor material 40. However, the TSV 25 is fabricated as a capacitor structure that includes a via 45 that serves as one capacitor plate, a doped semiconductor region 50 that serves as a second capacitor plate and is separated electrically and laterally from the via 45 by way of a liner insulating layer 55 that functions as a capacitor dielectric. The TSV capacitor 25 may be a cylindrical structure in that the via 45 may be cylindrical, the capacitor dielectric 55 may be a cylindrical shell and the doped region 50 may also approximate the structural characteristics of the cylindrical shell. The cylindrical nature of the TSV capacitor 25 will be evident in subsequent figures.

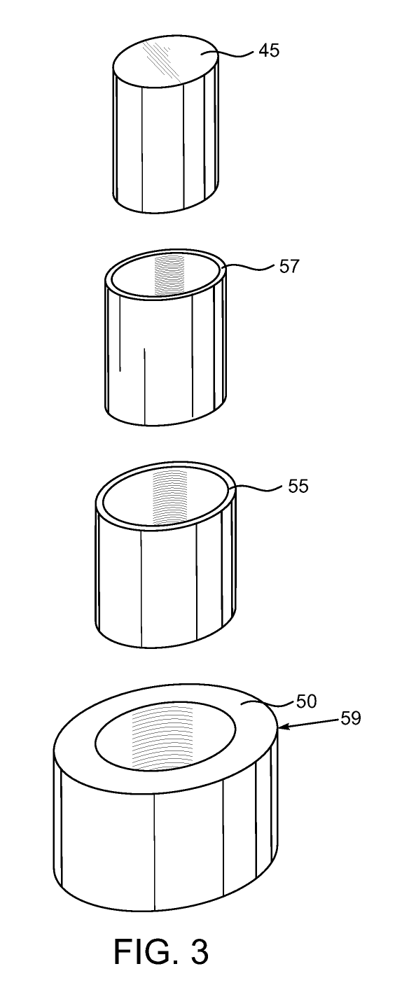

Additional details of the TSV capacitor 25 may be understood by referring now to FIG. 3. FIG. 3 is an exploded pictorial view of the TSV capacitor 25. The via 45 is shown exploded from an optional barrier layer 57, which may be used in circumstances where lateral diffusion of the material used for the via 45 is contemplated and potentially problematic. The barrier layer 57 is shown exploded from the capacitor dielectric 55, which is in-turn shown exploded from the doped region 50. The via 45 may be constructed from a variety of conductive materials such as, for example, copper, gold, silver, aluminum, tantalum, titanium, nickel, vanadium, combinations of these or others. It might even be possible to construct the via 45 from other types of conducting materials such as, doped polysilicon or others. The via 45 may be fabricated using well-known plating, chemical vapor deposition (CVD), physical vapor deposition (PVD), combinations of these or other material application techniques. The barrier layer 57 may be composed of a variety of materials that inhibit diffusion of the via 45, such as tantalum, nickel, vanadium, combinations of these or others and fabricated using the same types of techniques.

As described above, the doped region 50 may consist of a cylindrical shell portion of the semiconductor material 40 depicted in FIG. 2. The external border 59 of the doped region 50 is somewhat artificial and shown here merely for explanatory purposes. The lateral borders of any such doped regions in semiconductor fabrication are seldom if ever distinct and crisp but rather represent gradations or some gradation of impurity concentration. The doped region 50 is advantageously fabricated by a selective doping of the semiconductor material 40 depicted in FIG. 2 to render the semiconductor material 40 conductive. The dopant(s) may be introduced by ion implantation, diffusion or other impurity introduction techniques. Depending upon the type of fabrication process, that is CMOS or NMOS, the doped region 50 might by either P-doped or N-doped as desired. In any event, the goal is to render the doped region conductive by way of the introduction of appropriate impurities.

The insulating liner 55 may be constructed from a variety of insulating materials, such as those commonly used for TSV fabrication like SiO₂ or Si₃N₄. However, other dielectric materials, which have higher dielectric constants than silicon dioxide such as HfO₂, Ta₂O₅, ZrO₂ or others may be used to provide greater capacitance for the TSV capacitor 25. The following table shows a few possible candidates and corresponding dielectric constants.

| Material | Dielectric Constant ε₀ |
|---|---|
| SiO₂ | 3.9 |
| Si₃N₄ | 7.5 |
| ZrO₂ | 12.5 |
| HfO₂ | 25 |
| Ta₂O₅ (α phase) | 30 |

The capacitor dielectric 55 may be constructed using thermal oxide growth techniques, CVD, or other material application techniques. It should be understood that while a generally cylindrical TSV capacitor structure is disclosed herein, other shapes may be used for the via 45, the doped region 50 and the capacitor dielectric 55 besides cylindrical and/or circular shapes. It should be noted that the via 30 and the insulating liner 35 of the TSV 20 shown in FIGS. 1 and 2 may be fabricated from the same materials and techniques for the corresponding features of the TSV capacitor 25 just described.

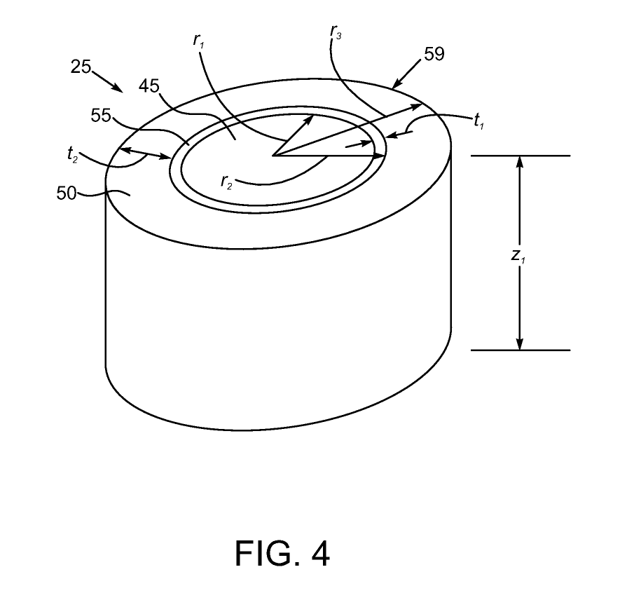

The capacitance for the TSV capacitor 25 and others like it is a function of the geometry of the various components of the TSV capacitor 25. This capacitance determination may be understood by referring now to FIG. 4, which is a pictorial view of the TSV capacitor 25 shown in FIG. 3 but unexploded and without shading so that various radii r₁, r₂ and r₃ may be more easily seen. In addition, the optional barrier layer 57 shown in FIG. 3 is subsumed into the via 45 for simplicity of illustration. The radius is the radius of the via 45. The radius r₁ may take on a variety of sizes. In an exemplary embodiment, r₁ may be about 2.0 to 20.0 microns. The radius r₂ is from the center of the via 45 to the outer edge of the capacitor dielectric 55 such that the thickness t₁ of the capacitor dielectric 55 is given by r₂−r₁. The thickness t₁ may take on a variety of sizes. In an exemplary embodiment, t₁ may be about 0.05 to 1.0 microns. The radius r₃ is the radius from the center of the via 45 to the outer edge 59 of the doped region 50 such that the thickness t₂ of the doped region 50 is given by:

t₂=r₃−(t₁+t₁) (1)

The thickness t₂ may take on a variety of sizes. In an exemplary embodiment, t₂ may be about 20.0 to 100.0 microns. Again it should be understood that the quantity t₂ does not represent a precise outer lateral boundary of the doped region 50. Since the doped region 50 will typically be grounded, the thickness t₂ may be varied according to the desired packing density of the TSV capacitor 25 and the other TSVs 15 shown in FIG. 1. The quantity z₁ is the height of the via 45, the doped region 50 and the capacitor dielectric 55. The capacitance C of the TSV capacitor 25 is given by

$$C = \frac{2 π κ {ɛ}_{0}}{ln [ \frac{{r}_{2}}{{r}_{1}} ]} ( {z}_{1} ) \qquad ( 2 )$$

where κ is the dielectric constant of the capacitor dielectric 55 and ∈₀ is the permittivity constant 8.854×10⁻¹² C²/N·m². These units may be converted as necessary to match the units (i.e., nm, microns etc.) of the relevant geometries of the TSV capacitor 25 or vice versa. The capacitance C per TSV capacitor 25 may be increased by decreasing the thickness t₁ (i.e., decreasing r₂), increasing the dielectric constant κ, increasing the height z₁ or some combination of these factors. Assuming a constant capacitance per TSV capacitor of the semiconductor substrate 10 (see FIG. 1) the total capacitance Cₜₒₜₐₗ provided by the TSV 25 and the other TSV capacitors is given by:

Cₜₒₜₐₗ=xC (3)

where x is the total number of TSV capacitors 25 in the semiconductor substrate 10. Of course, it may be possible to fabricate the TSV capacitor 25 with one geometry and other TSV capacitors with smaller or larger geometries as desired. In that circumstance, the calculation of Cₜₒₜₐₗ will need to be broken out to account for the different sizes of the TSV capacitors (TSV 25 and others).

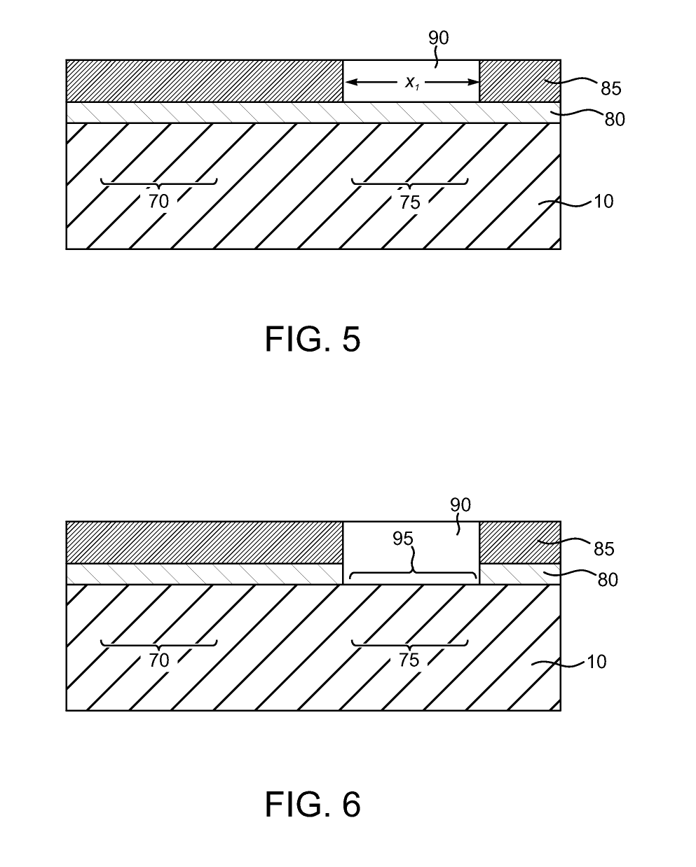

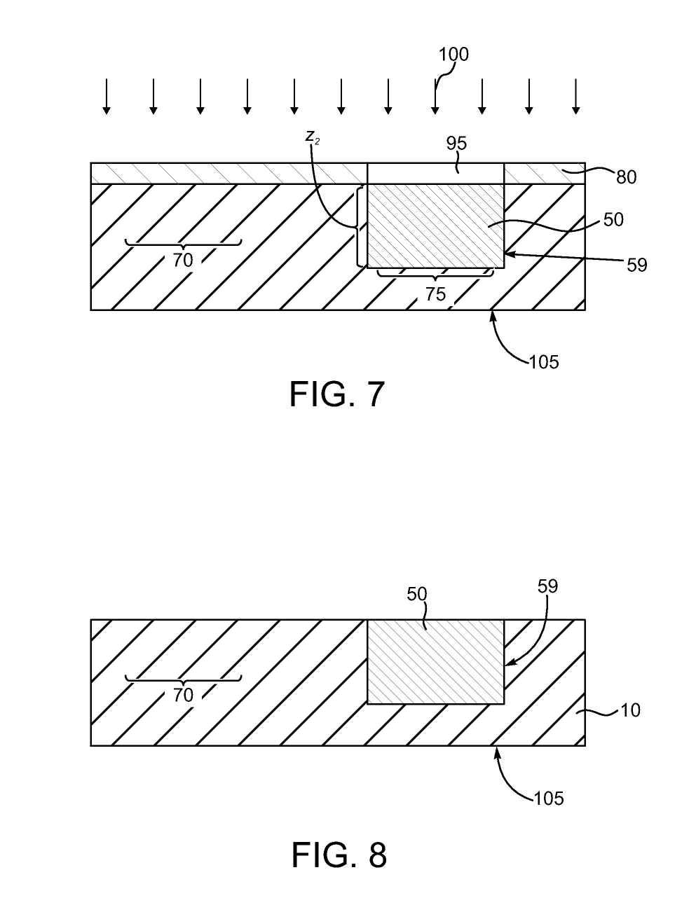

An exemplary method for fabricating the TSV 20 and the TSV capacitor 25 depicted in FIGS. 1, 2 and 3 may be understood by referring now to FIGS. 5-12 and initially to FIG. 5. FIG. 5 is a sectional view of the semiconductor substrate 10 taken at section 5-5 depicted in FIG. 1 but prior to the fabrication of the TSV 20 and the TSV capacitor 25. Here, a region 70 of the semiconductor substrate 10 is slated for the ultimate fabrication of the TSV 20 depicted elsewhere and a region 75 of the semiconductor substrate 10 is slated for the ultimate fabrication of the TSV capacitor 25 depicted elsewhere herein. The semiconductor substrate 10 may, in this illustrative embodiment, be a lightly p-doped silicon substrate doped with boron or other p-type impurities. A dielectric hard mask 80 may be fabricated on the semiconductor substrate 10 using a variety of materials and techniques. For example, a thermal or CVD SiO₂, a CVD Si₃N₄ or any of a variety of other dielectric materials may be applied that are suitable for hard mask purposes against an ion implantation step. In an exemplary embodiment, the dielectric hard mask 80 may be about 100 to 200 microns in thickness although this thickness range may be varied according to design discretion. The dielectric hard mask 80 will serve as a hard mask to prevent a subsequent ion introduction step from changing the impurity level of the region 70. An etch mask 85 is fabricated on the hard mask 80 and patterned with a suitable hole 90 which has a lateral dimension x₁ that will set the initial lateral extent of the later formed doped region 50 depicted elsewhere herein. Next and as shown in FIG. 6, a hole 95 may be etched in the hard mask 80 over the region 75 but not over the region 70. The hole 95 may be created by way of plasma etching such as reactive ion etching, or non-directional etching such as by way of wet etching processes. The etch chemistry suitable to create the hole 95 will depend upon the composition of the hard mask 80. For example, a SiO₂ hard mask 80 may be etched using CF₄ or SF₆. Following the creation of the hole 95, the mask 85 may be stripped from the semiconductor substrate 10 using well-known ashing, solvent stripping or combinations of the two.

With the hard mask 80 patterned with the hole 95, the semiconductor substrate 10 may be subjected to an ion implantation step involving the implantation of n-type ions 100. The ions 100 pass through the hole 95 to create the doped region 50 at the region 75 while the region 70 remains masked and relatively unaffected by the implant. Various n-type dopants such as phosphorous or arsenic may be used. Well-known dosages, energies and durations may be used to establish the doped region 50. Optionally, an ion diffusion process may be used to introduce the n-type ions 100. The term “doped region” is intended to mean that the doped region 50 has a majority concentration of an impurity type, i.e., n-type or p-type, that is opposite to the doping type of the surrounding portion of the semiconductor substrate 10. For example, the doped region 50 may be a majority n-type impurity concentration in an otherwise p-doped substrate and vice versa.

It should be understood that at least one anneal process should be performed on the semiconductor substrate 10 to repair crystalline damage associated with the creation of the doped region 50. This anneal step may be performed using a variety of thermal parameters and is designed to both repair crystalline damage and also to essentially activate the dopant within the doped region 50. It should be understood that the anneal process may cause the lateral border 59 of the doped region 50 to expand laterally as the dopants diffuse during the thermal process. Note that the introduction of the ions is performed such that the doped region 50 does not extend to the bottom 105 of the interposer. The doped region 50 is preferably established to some depth z₂, which will typically be less than the full depth of the semiconductor substrate 10 at this stage. As described more fully below, the semiconductor substrate 10 may subsequently undergo a thinning process. However, if sufficient energy and time is applied, the doped region 50 could extend all the way to the bottom 105 as desired.

Following the introduction of the ions 100, the hard mask 80 may be stripped to leave the doped region 50 in the interposer as shown in FIG. 8. Processing to create the TSV 20 (see FIG. 1) in the region 70 may now proceed.

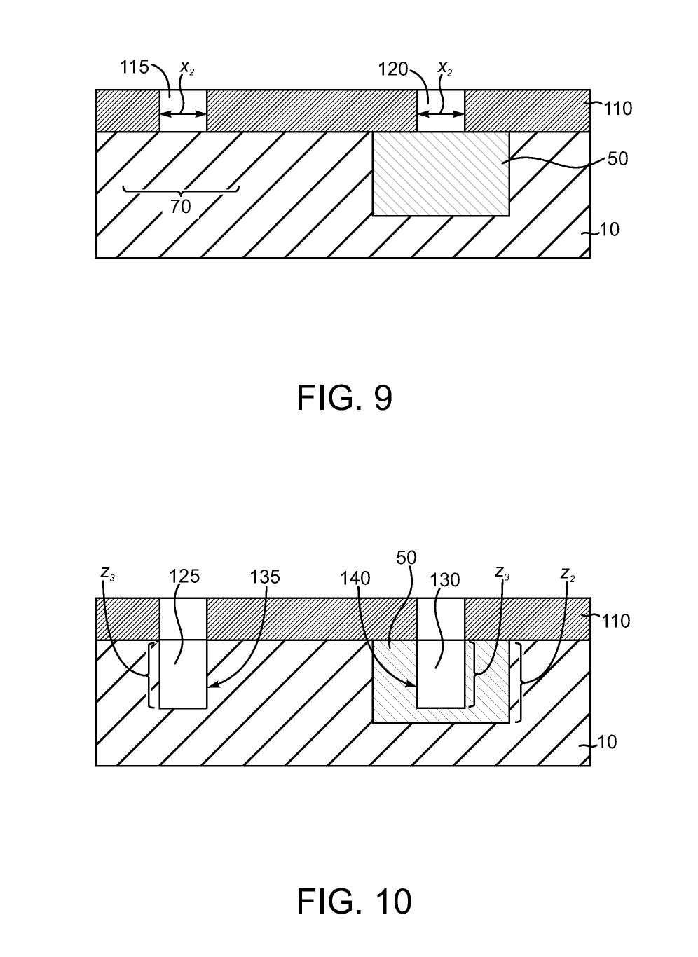

Next and as shown in FIG. 9, a suitable mask 110 is fabricated on the semiconductor substrate 10 and patterned with a suitable hole 115 over the region 70 and another suitable hole 120 over the doped region 50. The mask 110 will serve as an etch mask against subsequent etching of the interposer to be described in more detail below. The mask 110 may be composed of resist and applied and patterned using well-known photolithography techniques. The holes 115 and 120 may have some lateral dimension x₂ which will typically be somewhat larger than the ultimate width 2r₁ (see FIG. 4) of the later formed via 45. Each of the holes 115 and 120 may have the lateral dimension x₂ or they may have different dimensions as desired.

Next and as shown in FIG. 10, a deep etch process may be performed with the mask 110 in place to establish holes 125 and 130. The hole 125 is at the region 70 and the hole 130 is in the doped region 50. The holes 125 and 130 may have some depth z₃, which may be about 100 to 400 microns in an exemplary embodiment. If desired, the sidewalls 135 and 140 of the holes 125 and 130, respectively, may be tapered or straight. If tapered, the sidewalls 135 and 140 may taper inwardly as a function of depth and this tapering may be accomplished by varying the etch chemistry and energy during the etching process. The etch may be by way of plasma etching, such as RIE, using etch chemistries suitable for the material of the semiconductor substrate 10. For example, silicon may be etched using CF₄, SF₆ or Cl₂. Note that z₃ may be less than z₂ as shown or greater than z₂ as desired. This flexibility in the relationship between the depths z₃ and z₂ is possible because the later-formed capacitor dielectric 55 (see FIGS. 2-4) will establish the requisite electrical isolation in either case.

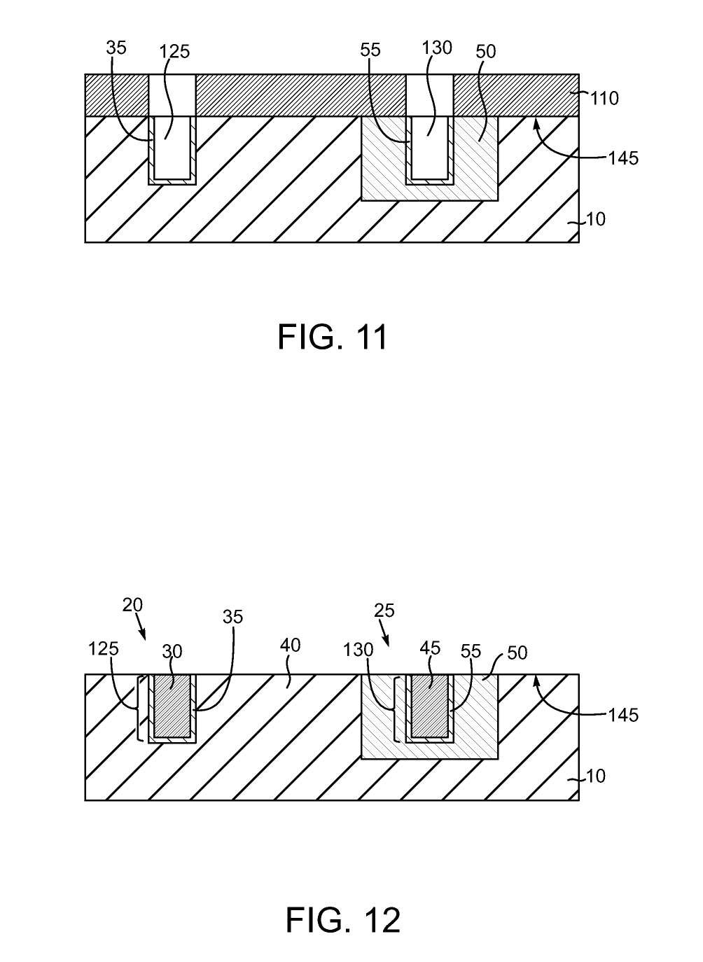

Next and as shown in FIG. 11, the liner dielectrics 35 and 55 may be established in the semiconductor substrate 10 and in particular in the holes 125 and 130. As noted above, a variety of materials and techniques may be used to establish the liner dielectrics 35 and 55 such that the liner dielectric 55 serves as the capacitor dielectric. The process to fabricate the liner dielectrics 35 and 55 may be performed with the mask 110 in place so that an upper surface 145 of the semiconductor substrate 10 is not covered by the material used to form the liner dielectrics 35 and 55. Optionally, the mask 110 may be removed and the upper surface 145 coated with the material used for the liner dielectrics 35 and 55 and that material left in place or removed by way of some material removal process.

Referring now to FIG. 12, and assuming the mask 110 shown in FIG. 11 is used during the process to fabricate the liner dielectrics 35 and 55, that mask 110 may be stripped using ashing, solvent stripping or a combination of the two to leave the upper surface 145 of the semiconductor substrate 10 uncovered. Here, the holes 125 and 130 may be filled with conductive material to establish the vias 30 and 45. A variety of application techniques may be used to establish the vias 30 and 45 such as, for example, plating, CVD, PVD, or others, and using the materials disclosed elsewhere herein. In an exemplary embodiment, a barrier layer of tantalum (not visible but shown in FIG. 3) may be sputtered to a thickness of about 10 to 200 nm. Next a two-stage plating process involving a first electroless formation of a copper seed layer followed by a bulk plating process is used to establish the vias 30 and 45. These processes will typically coat the upper surface 145 of the semiconductor substrate 10 as well and that excess conductive material may be subsequently removed by way of an etch or chemical mechanical polishing process as desired. Optionally, the portions of the upper surface 145 of the semiconductor substrate 10 lateral to the holes 125 and 130 may be masked using resist or other mask materials and the material deposition process may be performed. At this point, the TSV 20 and the TSV capacitor 25 are essentially complete in that the via 30 is electrically isolated from the surrounding semiconductor material 40 of the semiconductor substrate 10 by way of the liner dielectric 35 and the TSV capacitor 25 consists of the via 45 and the doped region 50 serving as respective capacitor plates separated by the capacitor dielectric 55.

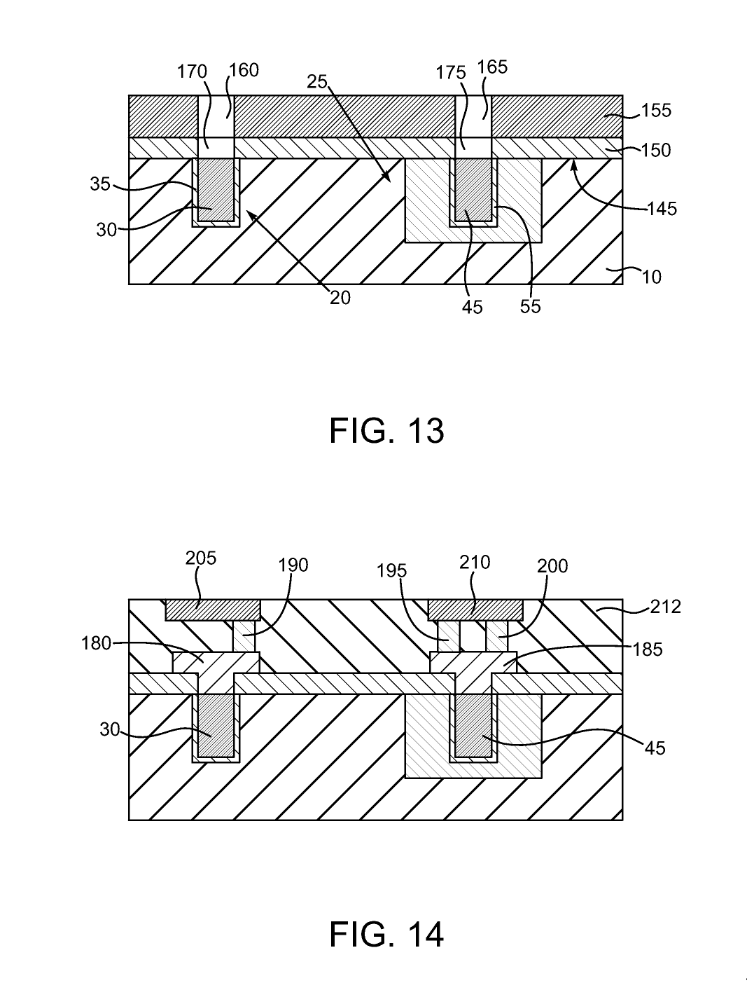

The interposer may be subjected to a variety of additional processing steps to establish external interconnect layers and interconnects so that the semiconductor substrate 10 may be connected to a printed circuit board or semiconductor chip or other device as desired. An exemplary method for forming these additional fabrication techniques may be understood by referring now to FIGS. 13-18 and initially to FIG. 13. A passivation layer or laminate 150 may be formed on the upper surface 145 of the semiconductor substrate 10. The passivation layer/laminate 150 may be composed of a variety of dielectric materials suitable for passivation such as silicon dioxide, silicon nitride, alternating layers of these or the like. Subsequently, an appropriate etch mask 155 may be formed on the passivation layer 150 and patterned with suitable holes 160 and 165 over the TSVs 20 and 25 respectively. With the mask 155 in place, a suitable etch process may be performed to establish holes 170 and 175 over the TSVs 20 and 25 respectively. The holes 170 and 175 may be formed by well-known material removal etching techniques of the types disclosed elsewhere herein and are designed to expose the vias 35 and 45 of the TSVs 20 and 25. However, the holes 170 and 175 should be patterned with care so that the liner dielectric layers 35 and 55 are not exposed or otherwise damaged during the process to establish the holes 170 and 175. The mask 155 may be stripped using ashing, solvent stripping, combinations of these or others.

Next and as shown in FIG. 14, a variety of metallization structures may be formed to establish electrical connections to the TSVs 20 and 25 respectively. For example, a via lands 180 and 185 may be fabricated in electrical contact with the vias 35 and 45 respectively. Thereafter one or more vias such as the via 190 may be fabricated on the via land 180 and the vias 195 and 200 may be established on the via land 185 and finally bump pads 205 and 210 may be fabricated in electrical contact with the vias 190, 195 and 200 respectively. Electrical isolation between the various conductor structures may be provided by way of a dielectric layer 212 which is shown as a unitary layer on the passivation laminate 150, but which may actually consist of multiple layers of dielectric material applied in succession. In an exemplary embodiment, each interlevel dielectric may consist of a SiCN layer topped with a thicker layer of SiO₂. The via lands 180, 185, the vias 190, 195, 200 and the bump pads 205 and 210 may be fabricated using well-known material deposition/application techniques and materials such as those disclosed elsewhere herein in conjunction with the TSVs. The bump pads 205 and 210 may be designed to be electrically connected to solder bumps, conductive pillars or other types of interconnect structures.

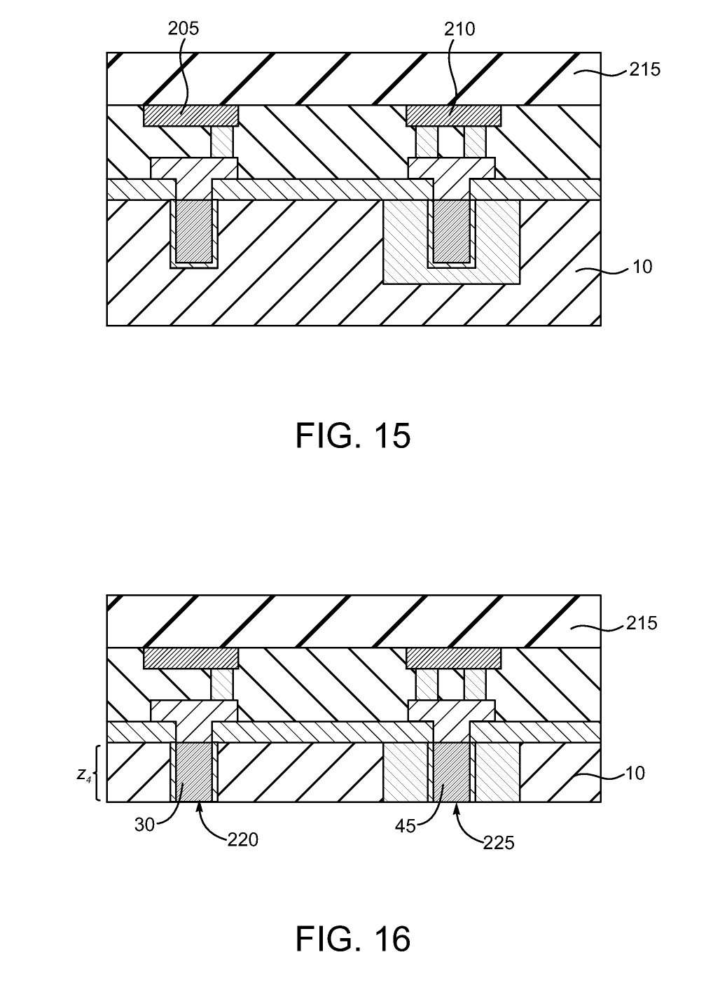

Next and as shown in FIG. 15, a carrier wafer 215 may be connected to the semiconductor substrate 10 so as to cover the bond pads 205 and 210. The carrier wafer 215 is designed to facilitate the easy handling of the interposer during subsequent processing as well as to protect the interconnect structures such as the bond pads 205 and 210. At this stage, the semiconductor substrate 10 has not reached its final thickness. Next and as shown in FIG. 16, the semiconductor substrate 10 may undergo a thinning process with the carrier substrate 215 in place to reduce the thickness of the semiconductor material down to some thickness z₃ and in the process expose the lower ends 220 and 225 of the vias 35 and 45. This thinning process may be performed using well-known lapping or other thinning techniques. The thickness z₃ may take on a variety of values depending upon the design requirements for the semiconductor substrate 10. In an exemplary embodiment, the thickness z₃ may be about 60-200 microns.

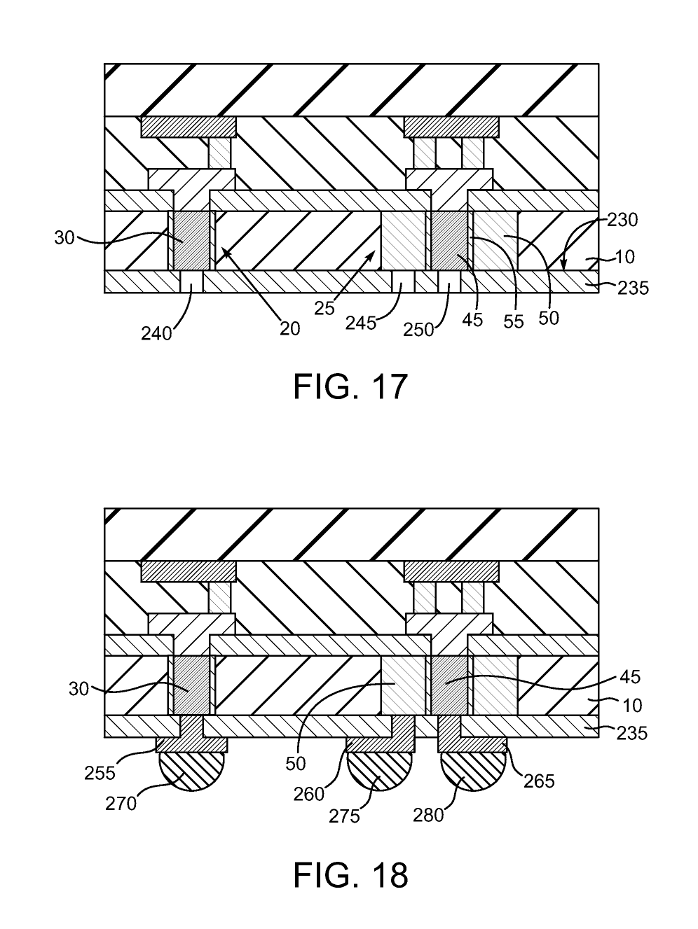

Interconnect structures may be fabricated to establish contact with the TSVs 20 and 25 at a lower side 230 of the semiconductor substrate 10. In this regard, attention is now turned to FIG. 17. A passivation layer 235 or laminate may be formed on the side 230 of the semiconductor substrate 10 and patterned to form a hole 240 to expose the via 35 and a hole 245 to expose a portion of the doped region 50 of the TSV 25 and another hole 250 to expose a portion of the via 45. The holes 240, 245 and 250 may be fabricated using the same types of techniques and materials disclosed above in conjunction with the holes 170 and 175 depicted in FIG. 13. Of course it is desirable to ensure that the holes 245 and 250 are sufficiently laterally separated from the liner dielectric 55 to avoid shorting the TSV capacitor 25. Next and as shown in FIG. 18, bump pads 255, 260 and 265 may be fabricated in electrical contact with the via 35, the doped region 50 and the via 45, respectively. Portions of the pads 255, 260 and 265 may spread across the passivation layer 235 as shown. Subsequently, solder interconnect structures 270, 275 and 280 may be fabricated on the pads 255, 260 and 265 respectively. The solder interconnect structures 270, 275 and 280 may be solder bumps, conductive pillars or other types of interconnect structures may be fabricated using well known lead based or lead free solders as desired. Interconnect structures 270, 275 and 280 enable the semiconductor substrate 10 to be mounted on another electrical device such as a PCB and electrically connected thereto.

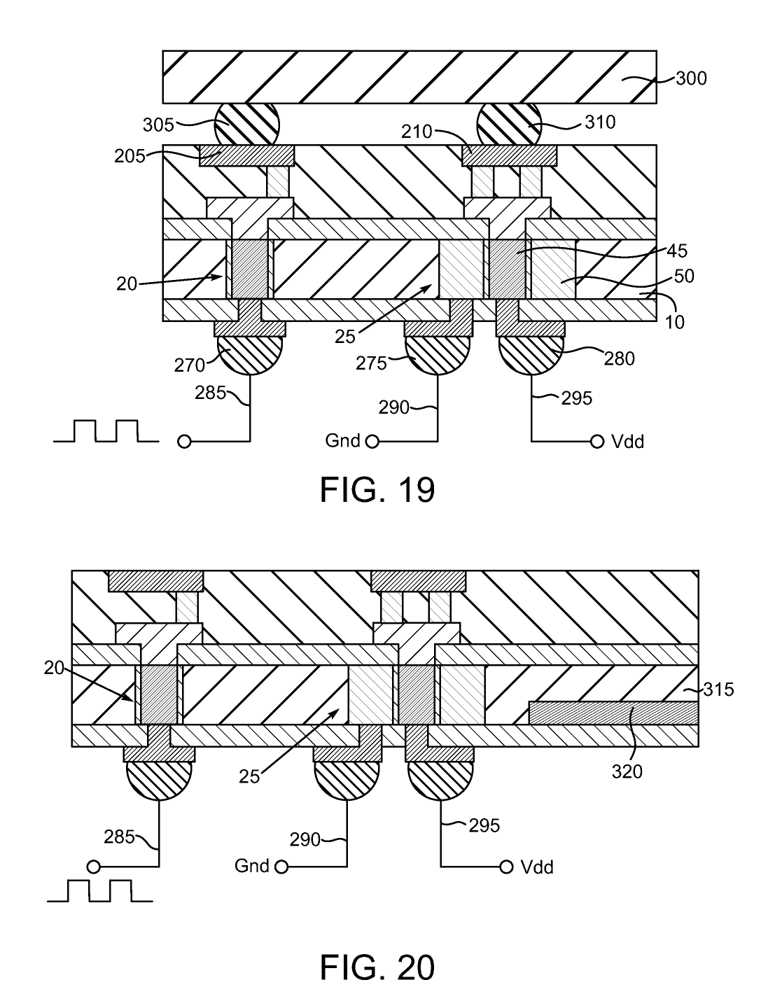

Some exemplary electrical connections for the semiconductor substrate 10 may be understood by referring now to FIG. 19 which shows the semiconductor substrate 10 connected to a signal input 285, a ground input 290 and a voltage or Vdd input 295 by way of the solder interconnect structures 270, 275 and 280 respectively. A semiconductor chip 300 may be mounted to the semiconductor substrate 10 and electrically connected thereto by way of the pads 205 and 210 and interconnect structures 305 and 310 of the semiconductor chip 300. Here, the signals may be propagated from the input 285 through the semiconductor substrate 10 and to the interconnect 305 of the chip 300 by way of the TSV 20 and the voltage input 295 may be capacitively coupled across the TSV cap 225 by way of the solder interconnect 280, the via 45 and up through the interconnect 310 of the chip 300. While the ground input is tied to the doped region 50 (the other capacitor plate) of the TSV capacitor 25 by way of the solder interconnect 275. These TSVs serving as straight conductive pathways and/or capacitive pathways may be propagated across the entirety of the semiconductor substrate 10 where some portion of the total number of TSVs for the semiconductor substrate 10 may be devoted to signal and others may be implemented as TSV capacitors as desired.

In the foregoing illustrative embodiments, the TSV capacitor 25 is implemented in a semiconductor substrate 10 as shown in the various figures. However, the skilled artisan will appreciate that the concept of a TSV cap may be implemented in a semiconductor substrate, such as a semiconductor chip, with active circuitry. In this regard, attention is now turned to FIG. 20, which is a sectional view like FIG. 19 but without the semiconductor chip 300 depicted. In this illustrative embodiment, the TSV 20 and the TSV capacitor 25 are implemented in a semiconductor chip 315, which includes an active region 320 that is composed of huge numbers of integrated circuit components, such as transistors, resistors and other devices. It may be necessary to position TSVs, such as a TSV 20 and the TSV capacitor 25, lateral to the active region 320 in order to avoid damaging the active region 320 during the fabrication steps necessary for the TSVs 20 and 25 as shown. In any event, the inputs 285, 290 and 295 may function for the semiconductor chip 315 much in the same way as described above in conjunction with FIG. 19. The semiconductor chip 315 may be any of a variety of different types of integrated circuits, such as, such as integrated circuits dedicated to video processing, central processing units (CPU), graphics processing units (GPU), accelerated processing units (APU) that combines microprocessor and graphics processor functions, a system-on-chip, application specific integrated circuits, memory devices, active optical devices, such as lasers, passive optical devices or the like.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

1. A method of manufacturing a capacitor, comprising:
forming a doped region of a first impurity type in a portion of a semiconductor substrate, the portion of the semiconductor substrate being doped with a second and opposite impurity type, the first doped region being operable to function as a first capacitor plate;
forming a first via hole in the doped region, the first via hole having a first sidewall;
forming a first insulating layer on the first sidewall, the first insulating layer being operable to function as a capacitor dielectric; and
forming a first conductive via in the first via hole, the first conductive via being operable to function as a second capacitor plate.

2. The method of claim 1, wherein the doped region is formed by ion implantation.

3. The method of claim 1, wherein the first conductive via comprises a through silicon via.

4. The method of claim 1, comprising fabricating a second via hole having a second sidewall and being positioned outside the doped region, a second insulating layer on the second sidewall and a second conductive via in the second via hole.

5. The method of claim 4, wherein the second via comprises a through silicon via.

6. The method of claim 1, wherein the semiconductor substrate comprises an interposer.

7. The method of claim 1, wherein the semiconductor substrate comprises a semiconductor chip.

8. The method of claim 1, comprising coupling the first conductive via to power and the doped region to ground.

9. A method of manufacturing, comprising:
fabricating a plurality of through silicon vias in a semiconductor substrate; and
fabricating a plurality of through silicon via capacitors in the semiconductor substrate by forming plural doped regions of a first impurity type plural portions of a semiconductor substrate, the portions of the semiconductor substrate being doped with a second and opposite impurity type, the doped regions being operable to function as first capacitor plates, forming plural first via holes in the doped regions, the first via holes having first sidewalls, forming plural first insulating layers on the first sidewalls, the first insulating layers being operable to function as capacitor dielectrics, and forming plural first conductive vias in the first via holes, the first conductive vias being operable to function as second capacitor plates.

10. The method of claim 9, wherein the doped regions are formed by ion implantation.

11. The method of claim 9, wherein the semiconductor substrate comprises an interposer.

12. The method of claim 9, wherein the semiconductor substrate comprises a semiconductor chip.

13. The method of claim 9, comprising mounting a semiconductor chip on the semiconductor substrate and electrically connecting the semiconductor chip to at least one of the through silicon via capacitors.

14. An apparatus, comprising:
a semiconductor substrate having a portion doped with a first impurity type; and
a doped region of a second impurity type in the portion of the semiconductor substrate, the doped region being operable to function as a first capacitor plate;
a first via hole in the doped region, the first via hole having a first sidewall;
a first insulating layer on the first sidewall, the first insulating layer being operable to function as a capacitor dielectric; and
a first conductive via in the first via hole, the first conductive via being operable to function as a second capacitor plate.

15. The apparatus of claim 14, wherein the doped region is formed by ion implantation.

16. The apparatus of claim 14, wherein the first conductive via comprises a through silicon via.

17. The apparatus of claim 14, comprising a second via hole having a second sidewall and being positioned outside the doped region, a second insulating layer on the second sidewall and a second conductive via in the second via hole.

18. The apparatus of claim 17, wherein the second via comprises a through silicon via.

19. The apparatus of claim 14, wherein the semiconductor substrate comprises an interposer.

20. The apparatus of claim 14, wherein the semiconductor substrate comprises a semiconductor chip.
